(19) United States
(12) Patent Application Publication
(10) Pub. No.: US 2013/0050961 A1
(43) Pub. Date: Feb. 28, 2013

(54) DEVICE AND METHOD FOR PROVIDING WATER RESISTANCE FOR A FLEXIBLE PRINTED CIRCUIT OR FLEXIBLE WIRE DEVICE

(71) Applicant: Sang Kyun KANG, Seoul (KR)

(72) Inventor: Sang Kyun KANG, Seoul (KR)

(73) Assignee: Pantech Co., Ltd., Seoul (KR)

(21) Appl. No.: 13/566,435

(22) Filed: Aug. 3, 2012

(30) Foreign Application Priority Data
Aug. 24, 2011 (KR) 10-2011-0084463

(51) Int. Cl. H05K 5/02; B32B 38/10

(52) U.S. Cl. 361/749; 156/257

(57) ABSTRACT

A folder-type and a non-folder device with a flexible printed circuit (FPC) or flexible printed wire, include: a first case portion, a second case portion having a groove, the groove on a side of the second case portion adjacent to the first case portion; an elastic portion shaped to fit in the groove, and the elastic portion having an opening; and an adhesive layer in between the first case portion and the second case portion. The adhesive layer fixes the first case portion with the second case portion, the elastic portion is disposed within the groove, and the FPC is disposed within the opening.

### CROSS-REFERENCE TO RELATED APPLICATION

This application claims priority from and the benefit under 35 U.S.C. §119(a) of Korean Patent Application No. 10-2011-0084463, filed on Aug. 24, 2011, which is incorporated by reference for all purposes as if fully set forth herein.

### BACKGROUND

1. Field

The present disclosure relates to a Flexible Printed Circuit (FPC) water-proofing structure and a method for providing water resistance for a flexible printed circuit or flexible wire device.

2. Discussion of the Background

A Flexible Printed Circuit (FPC) may refer to a flexible printed circuit and may also refer to a flexible wire (FW) or flexible circuitry (FC). A FPC device has wiring with pliability and flexibility, and may have a fine circuit disposed between a polyimide base and a cover layer providing insulation and heat resistance. As used in this disclosure, “water-proofing” may refer to water resistance, or improving a device or structures resistance to damage caused by incidental water contact, or water-proofing according to an industry or commercial standard.

FIG. 1 illustrates a general flexible printed circuit (FPC) water-proofing structure according to the prior art. FIG. 2 is a cross-sectional view illustrating the FPC water-proofing structure of FIG. 1, taken along the line A-A.

Referring to FIG. 1 and FIG. 2, the FPC 140a and FPC 140b electrically connect first structures 100a and 100b with second structures 100c and 100d, which are ends of a folder-type electronic device. The first structures 100a and 100b and the second structures 100c and 100d may be separated into outer cases 100a and 100d and inner cases 100b and 100c. Folder-type electronic devices may include electronic devices in which a display and an input unit, respectively, are the first structures 100a and 100b (display) and the second structures 100c and 100d (the input unit), and is connected by a hinge structure. Some examples of these folder-type electronic devices may be portable terminals, laptops, and the like.

In order to water-proof FPC 140a and FPC 140b, the FPC 140a and FPC 140b are inserted into elastic bodies 130a and 130b, and are respectively inserted in openings 150a and 150b of the first structures 100a and 100b and the second structures 100c and 100d. A water-proofing double-sided tape 110a is separately applied and adhered between the outer cases 100a and 100d and the inner cases 100b and 100c.

In the above technique, since the elastic bodies 130a and 130b are inserted into the openings 150a and 150b with a uniformly looped curve shape, water-proofing may be ensured. However, if FPC 140a and FPC 140b are assembled, and FPC 140a and FPC 140b are inserted in a horizontal direction with respect to the elastic bodies 130a and 130b, thereby making the assembling difficult. In addition, in the above technique, because a looped curve shape results, an increase of an overall thickness of the electronic device may occur.

FIG. 3 is a perspective view illustrating a general portable terminal according to the prior art. FIG. 4 is a cross-sectional view illustrating the portable terminal of FIG. 3, taken along the line X-X′ according to the prior art.

Referring to FIG. 3 and FIG. 4, a packing 7 in which the FPC 6 is inserted is placed along an inner case 5, which may allow a free assembly, and may consume a relatively small amount of space. The device may achieve this because not much space is used for the horizontal insertion of the packing 7. However, after the packing 7 is placed along the inner case 5, and within wall 8, a holder 11 and a screw 12 are separately applied to compress the inner case 5 to the outer case 4 in order to provide water-proofing. A wall 13 may be placed in between the outer case 4 and the wall 8 as well. Thus, the addition of these elements cause an increase in the thickness direction of the device. If the screw 12 is installed through the outer case 4 in order to reduce the thickness, because the holder 11 is not used, the screw 12 may be exposed to the outside, thereby reducing the options for design.

The above information disclosed in this Background section is only for enhancement of understanding of the background of the invention and therefore it may contain information that does not form any part of the prior art.

### SUMMARY

Exemplary embodiments of the present invention provide a device and method for providing water resistance for a flexible printed circuit or flexible wire device. The terminal may be a folder-type device and a non-folder type device.

Additional features of the invention will be set forth in the description which follows, and in part will be apparent from the description, or may be learned by practice of the invention.

An exemplary embodiment of the present invention discloses a folder-type device with a flexible printed circuit (FPC), including: a first case portion; a second case portion having a groove, the groove on a side of the second case portion adjacent to the first case portion; an elastic portion disposed in the groove, and the elastic portion having an opening; and an adhesive layer in between the first case portion and the second case portion, wherein the adhesive layer fixes the first case portion with the second case portion, and the FPC is disposed within the opening.

An exemplary embodiment of the present invention discloses a method for waterproofing a flexible printed circuit (FPC) with a first case portion and a second case portion, including: forming a groove on a side of the second case portion adjacent to the first case portion; disposed an elastic portion in the groove; disposing an opening in the elastic portion; adhering the first case portion to the second case portion using an adhesive layer, wherein the adhesive layer fixes the first case portion with the second case portion, and the FPC is disposed within the opening.

An exemplary embodiment of the present invention discloses a non-folder type device with a flexible printed circuit (FPC), including: a case portion having a groove, the groove on a side of the case; an elastic portion shaped to fit in the groove, and the elastic portion having an opening; and an adhesive layer on the case portion, wherein the adhesive layer fixes to the case portion, the elastic portion is disposed within the groove, and the FPC is disposed within the opening.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 illustrates a general flexible printed circuit (FPC) water-proofing structure according to the prior art.

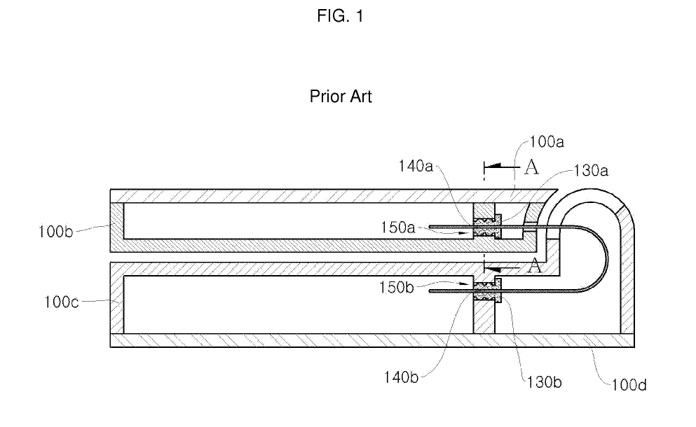

FIG. 2 is a cross-sectional view illustrating the FPC water-proofing structure of FIG. 1, taken along the line A-A.

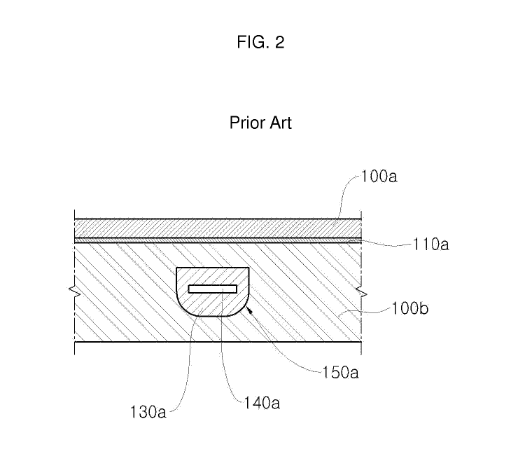

FIG. 3 is a perspective view illustrating a general portable terminal according to the prior art.

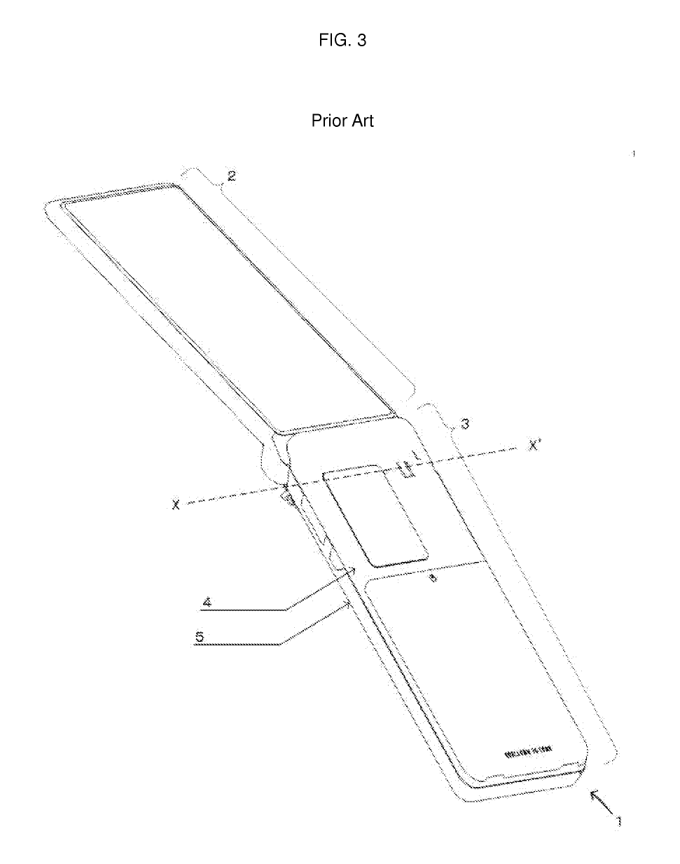

FIG. 4 is a cross-sectional view illustrating the portable terminal of FIG. 3, taken along the line X-X′ according to the prior art.

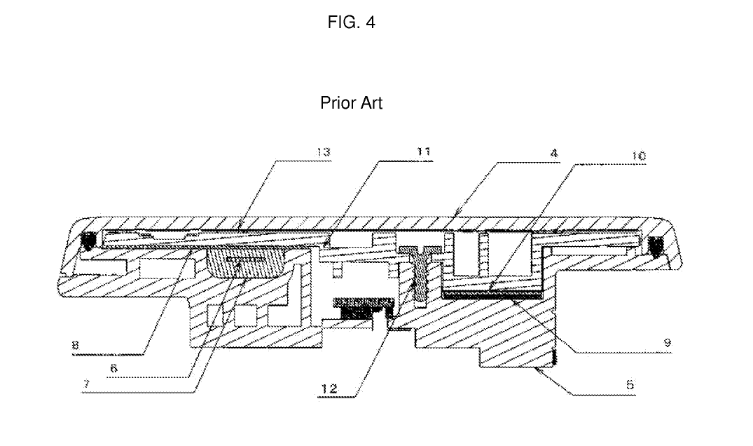

FIG. 5 is a perspective view illustrating a folder-type portable terminal according to an exemplary embodiment of the present invention.

FIG. 6 is a schematic view illustrating an FPC water-proofing structure, taken along the line X-X′ on the portable terminal of FIG. 5, according to an exemplary embodiment of the present invention.

FIG. 7 is a schematic view illustrating the FPC water-proofing structure, taken along the line X-X′ on the portable terminal of FIG. 5, according to an exemplary embodiment of the present invention.

FIG. 8 is a plane view illustrating the FPC water-proofing structure according to an exemplary embodiment of the present invention.

FIG. 9 is a cross-sectional view illustrating the FPC water-proofing structure of FIG. 8, taken along the line H-H′, according to an exemplary embodiment of the present invention.

FIG. 10 is a cross-sectional view illustrating the FPC water-proofing structure of FIG. 8, taken along the line P-P′, according to an exemplary embodiment of the present invention.

FIG. 11 is an enlarged partial perspective view illustrating the FPC water-proofing structure according to an exemplary embodiment of the present invention.

Throughout the drawings and the detailed description, unless otherwise described, the same drawing reference numerals will be understood to refer to the same elements, features, and structures. The relative size and depiction of these elements may be exaggerated for clarity, illustration, and convenience

### DETAILED DESCRIPTION OF THE ILLUSTRATED EMBODIMENTS

Exemplary embodiments now will be described more fully hereinafter with reference to the accompanying drawings, in which exemplary embodiments are shown. The present disclosure may, however, be embodied in many different forms and should not be construed as limited to the exemplary embodiments set forth therein. Rather, these exemplary embodiments are provided so that the present disclosure will be thorough and complete, and will fully convey the scope of the present disclosure to those skilled in the art. In the description, details of well-known features and techniques may be omitted to avoid unnecessarily obscuring the presented embodiments.

The terminology used herein is for the purpose of describing particular embodiments only and is not intended to be limiting of the present disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It will be understood that for the purposes of this disclosure, “at least one of X, Y, and Z” can be construed as X only, Y only, Z only, or any combination of two or more items X, Y, and Z (e.g., XYZ, XYY, YZ, ZZ).

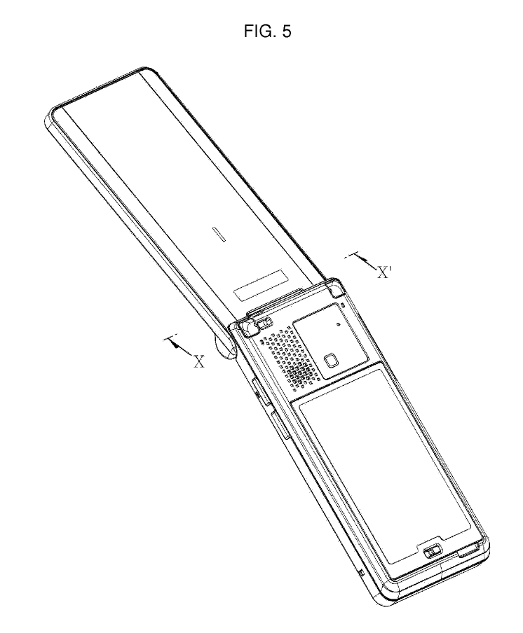

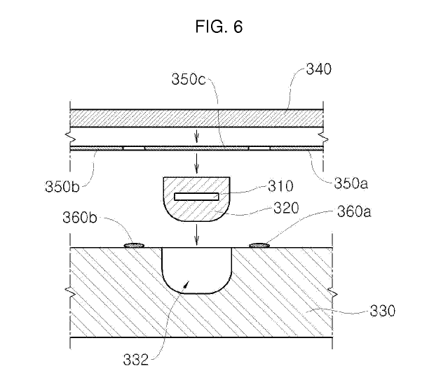

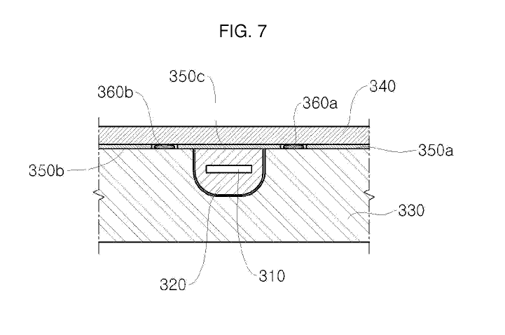

FIG. 5 is a perspective view illustrating a folder-type portable terminal according to an exemplary embodiment of the present invention. FIG. 6 is a schematic view illustrating an FPC water-proofing structure, taken along the line X-X′ on the portable terminal of FIG. 5, according to an exemplary embodiment of the present invention. FIG. 7 is a schematic view illustrating the FPC water-proofing structure, taken along the line X-X′ on the portable terminal of FIG. 5, according to an exemplary embodiment of the present invention.

Referring to FIG. 5, FIG. 6 and FIG. 7, the FPC water-proofing structure includes an elastic body 320 that encases a FPC 310, a first case 330, and a second case 340.

The first case 330 has a groove 332 in which the elastic body 320 is placed. The second case 340 is coupled to the first case 330 while being in contact with the elastic body 320.

In order to provide water-proofing between the first case 330 and the second case 340, water-proofing tapes 350a, 350b and 350c are attached to the first case 330 or the second case 340. In FIG. 7, the water-proofing tape 350c is attached to the upper surface of the elastic body 320, but a type of adhesive may also be applied thereto instead of the water-proofing tape 350c.

In order to enhance the adhesive strength between the first case 330 and the second case 340, the first case 330 or the second case 340 is coated with adhesives 360a and 360b. The water-proofing tapes 350a, 350b and 350c and the adhesives 360a and 360b are applied between the first case 330 and the second case 340 without using a mechanical coupling device, such as a screw, to provide an adhering technique that also provides water-proofing. This may allow a reduction of the thickness of the FPC device.

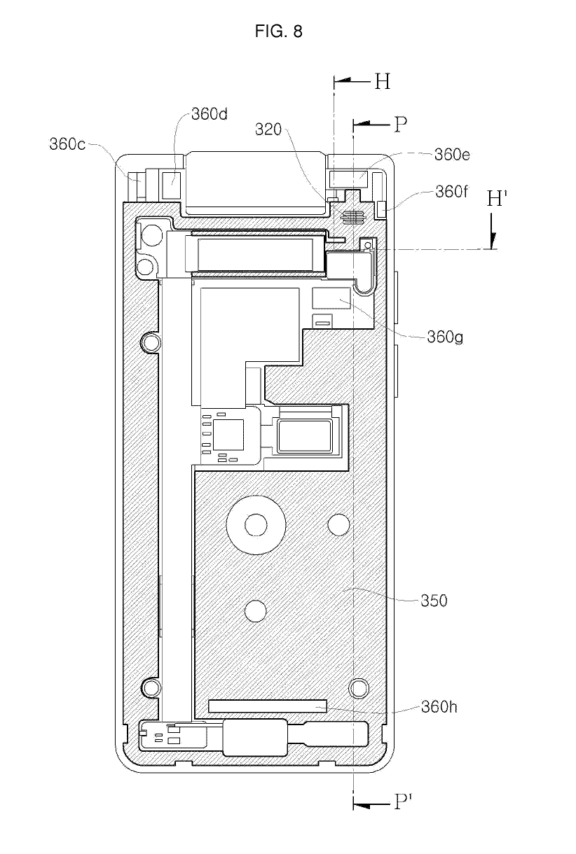

FIG. 8 is a plane view illustrating the FPC water-proofing structure according to an exemplary embodiment of the present invention.

Referring to FIG. 8, the water-proofing tape 350 is attached so as to surround the region where the elastic body 320 is disposed, therefore encapsulating the surface of the elastic body 320.

In addition, the adhesives 360c, 360d and 360e may be applied to the region around the water-proofing tape 350, and in the region where the water-proofing tape 350 is applied, the water-proofing tape 350 may have portions removed so that the adhesives 360g and 360h may be applied to the regions where the water-proofing tape 350 has portions removed.

The placement and area of the water-proofing tape 350 and the adhesives 360c, 360d, 360e, 360g and 360h may change in various ways depending on the adhesive or water-proofing performance.

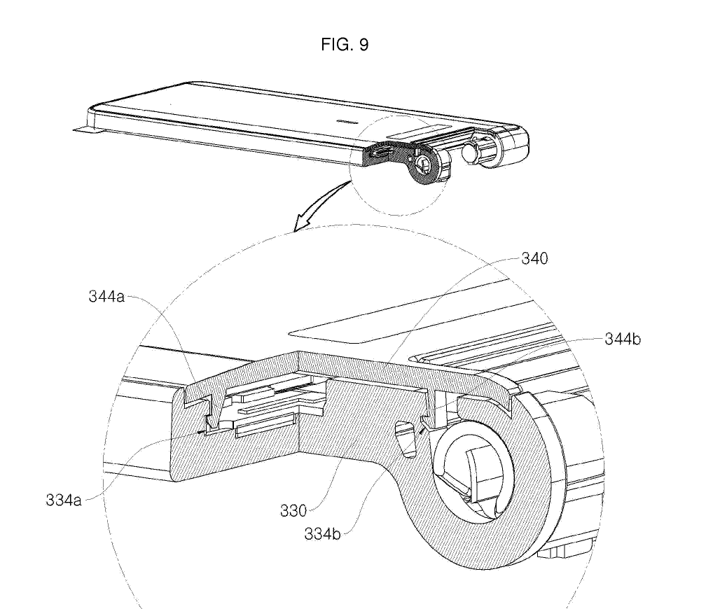

A hook structure (shown in FIG. 9 and described in more detail below) may be provided between the first case 330 and the second case 340 to enhance the coupling between the first case 330 and the second case 340.

FIG. 9 is a cross-sectional view illustrating the FPC water-proofing structure of FIG. 8, taken along the line H-H′, according to an exemplary embodiment of the present invention.

Referring to FIG. 9, the second case 340 has hooks 344a and 344b, and the first case 330 has hook coupling grooves 334a and 334b that may couple with the hooks 344a and 344b if the first case 330 and the second case 340 are aligned. The hook structure (hooks 344a and 344b engaged with hook coupling grooves 334a and 334b) may enhance the coupling forces between the first case 330 and the second case 340 and compress the elastic body 320 therein.

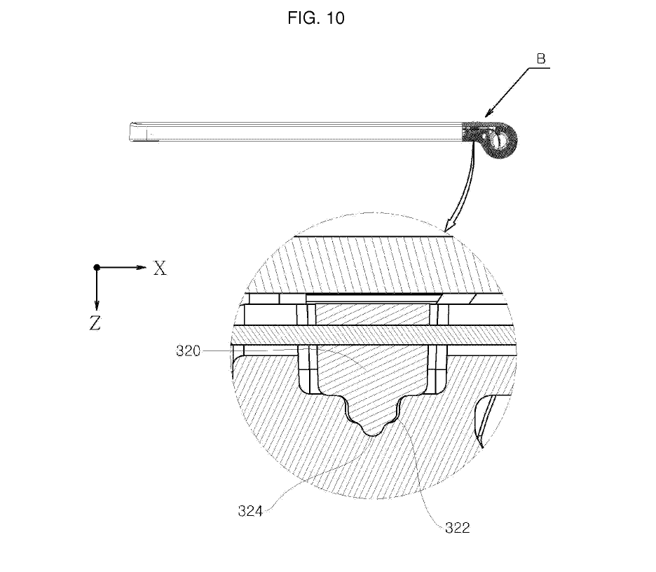

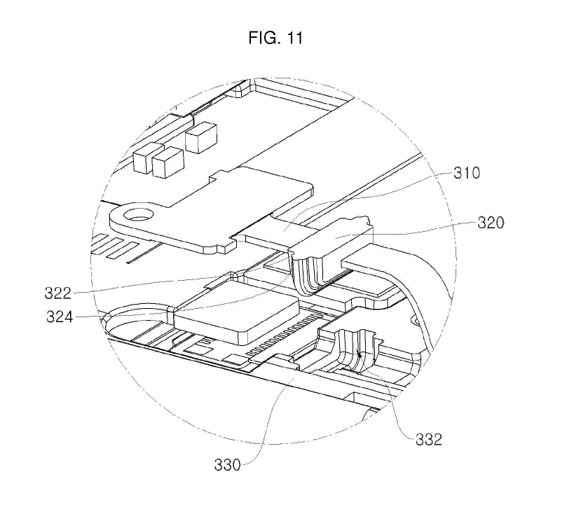

FIG. 10 is a cross-sectional view illustrating the FPC water-proofing structure of FIG. 8, taken along the line P-P′, according to an exemplary embodiment of the present invention. FIG. 11 is an enlarged partial perspective view illustrating the FPC water-proofing structure according to an exemplary embodiment of the present invention.

Referring to FIG. 10 and FIG. 11, the elastic body 320 has a first protrusive band 322 that protrudes along the side and lower surfaces of the elastic body 320. The first protrusive band 322 is compressed within the first case 330 in the vertical direction (in the Z-axial direction) and fits within the side and lower surfaces of the groove 332 (which is within an inner wall of the first case 330).

The elastic body 320 may further have a second protrusive band 324, in addition to the first protrusive band 322, that protrudes on the surface of the first protrusive band 322 with a smaller width than that of the first protrusive band 322. If the protrusive band has both the first protrusive band 322 and the second protrusive band 324, the water-proofing performance may be enhanced since there may be an increased contact surface area with the elastic body 320.

The groove 332 of the first case 330 has a shape that corresponds with the shape of the protrusive bands 322 and 324. Therefore, the elastic body 320 may be inserted into the groove 332 so that the side and lower surfaces of the elastic body 320 adhered to the first case 330. The water-proofing tape 350 may be attached or the adhesive 360 may be applied to the upper surface of the elastic body 320 to facilitate the water-proofing of the FPC device.

The water-proofing of the FPC structure may be applied to water proof various types of electronic device using FPC, such as cameras, camcorders and laptops, and it may also be applied to non-folding devices in the same way for implementing a water-proofing structure to a region where components mounted to a circuit are connected by using FPC, such as touch modules.

The FPC water-proofing structure may provide a reduction of space as compared to FPC devices that do not use an adhesive implementation. In addition, the FPC water-proofing structure may allow for more flexibility in design, due to the reduction of thickness and the ease of application of adhesives versus mechanical implements (such as the utilization of screws).

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A folder-type device with a flexible printed circuit (FPC), comprising:
a first case portion;
a second case portion having a groove, the groove on a side of the second case portion adjacent to the first case portion;
an elastic portion disposed in the groove, and the elastic portion having an opening; and
an adhesive layer in between the first case portion and the second case portion,
wherein the adhesive layer fixes the first case portion with the second case portion, and
the FPC is disposed within the opening.

2. The device according to claim 1, wherein the adhesive layer comprises water-proofing tape.

3. The device according to claim 1, wherein the first case portion comprises a hook, the second case portion comprises a hook grove, and the hook and the hook groove are engaged with each other.

4. The device according to claim 1, wherein the elastic portion comprises a first protrusion and a second protrusion, the second protrusion being narrower than the first protrusion, and
the groove is shaped to fit the elastic portion.

5. The device according to claim 2, wherein the water-proofing tape is used in end portions of the adhesive layer.

6. The device according to claim 1, wherein the adhesive layer is activated by the first case portion and the second case portion being compressed together.

7. The device according to claim 1, further comprising a hinge portion.

8. The device according to claim 2, wherein the water-proofing tape comprises a gap, and an adhesive is disposed in an area of the gap.

9. A method for waterproofing a flexible printed circuit (FPC) with a first case portion and a second case portion, comprising:
forming a groove on a side of the second case portion adjacent to the first case portion;
disposed an elastic portion in the groove;
disposing an opening in the elastic portion;
adhering the first case portion to the second case portion using an adhesive layer,
wherein the adhesive layer fixes the first case portion with the second case portion, and
the FPC is disposed within the opening.

10. The method according to claim 9, wherein the adhesive layer comprises water-proofing tape.

11. The method according to claim 9, wherein the first case portion comprises a hook, the second case portion comprises a hook grove, and the hook and the hook groove are engaged with each other when the first case portion and the second case portion are connected together.

12. The method according to claim 9, wherein the elastic portion comprises a first protrusion and a second protrusion, the second protrusion being narrower than the first protrusion, and
the groove is shaped to fit the elastic portion.

13. The method according to claim 10, wherein the water-proofing tape is used in end portions of the adhesive layer.

14. The method according to claim 9, wherein the adhesive layer is activated by the first case portion and the second case portion being compressed together.

15. The method according to claim 9, further comprising a hinge portion.

16. The method according to claim 10, wherein the water-proofing tape comprises a gap, and an adhesive is disposed in an area of the gap.

17. A non-folder type device with a flexible printed circuit (FPC), comprising:
a case portion having a groove on a side of the case;
an elastic portion disposed in the groove, and the elastic portion having an opening; and
an adhesive layer on the case portion,
wherein the adhesive layer adheres to the case portion, and
the FPC is disposed within the opening.

18. The device according to claim 17, wherein the adhesive layer is water-proofing tape.

19. The device according to claim 18, wherein the water-proofing tape is used in end portions of the adhesive layer.

20. The device according to claim 18, wherein the water-proofing tape has a gap, and an adhesive is disposed in an area of the gap.
